(19) United States
(12) Patent Application Publication
(10) Pub. No.: US 2006/0125052 A1
(43) Pub. Date: Jun. 15, 2006

(54) Lateral tunable capacitor and high frequency tunable device having the same

(76) Inventors: Seung Eon Moon, Daejeon-city (KR); Han Cheol Ryu, Seoul (KR); Young Tae Kim, Daejeon-city (KR); Min Hwan Kwak, Daejeon-city (KR); Su Jae Lee, Daejeon-city (KR); Kwang Yong Kang, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/210,015

(22) Filed: Aug. 22, 2005

(30) Foreign Application Priority Data
Dec. 13, 2004 (KR) 10-2004-0104918

(51) Int. Cl. H01L 29/93

(52) U.S. Cl. 257/595

(57) ABSTRACT

A lateral type tunable capacitor and a high frequency tunable device having the same are provided. The high frequency tunable device includes substrate; a signal line formed on the substrate; a plurality of tunable capacitors aligned on both sides of the signal line along the longitudinal direction of the signal line; an electrode disposed on the substrate for applying a DC voltage to the tunable capacitors. The tunable capacitor includes a dielectric layer formed on the substrate, and a first capacitor electrode and a second capacitor electrode formed on both sides of the dielectric layer on the substrate, and the first capacitor electrode, the dielectric layer, and the second capacitor electrode are aligned in parallel on the substrate.

### CROSS-REFERENCE TO RELATED PATENT APPLICATION

This application claims the benefit of Korean Patent Application No. 10-2004-0104918, filed on Dec. 13, 2004, in the Korean Intellectual Property Office, the disclosure of which is incorporated herein in its entirety by reference.

### BACKGROUND OF THE INVENTION

1. Field of the Invention

The present invention relates to technology for high frequency device parts, and more particularly, to a tunable capacitor and a high frequency tunable device having the same.

2. Description of the Related Art

A ferroelectric/paraelectric oxide thin film has various application fields due to its material characteristics. A high frequency tunable device having the ferroelectric/paraelectric uses a difference of permittivities due to changes of microscopic structure of the material when an electric field is applied to the ferroelectric/paraelectric. Examples of such a high frequency tunable device may include a phase shifter as a core component part of an active antenna system controlling its antenna direction electrically not mechanically, a frequency tunable filter using its permittivity change property of ferroelectric/paraelectric depending on applied electric fields, a voltage controlled capacitor, a voltage controlled resonator, voltage controlled oscillator, a voltage controlled distributor, and the like. Particularly, the ferroelectric/paraelectric phase shifter can be made thin-sized and light-weighted due to its high dielectric constant. Further, the ferroelectric/paraelectric phase shifter has many advantages as compared to other competing devices composed of ferromagnetics or semiconductors, such as lower power consumption due to low leakage current, fast response time, low production cost and high power capability.

In the meantime, a capacitor is one of the important elements in the high frequency tunable device fabricated using the ferroelectric/paraelectric thin film.

FIG. 1 is a view illustrating a conventional vertical type capacitor.

Referring to FIG. 1, the conventional capacitor includes a bottom electrode 12, a dielectric layer 14, and a top electrode 16, which are sequentially stacked in the vertical direction with respect to a substrate 10.

FIG. 2 is a view illustrating a conventional interdigital type capacitor.

Referring to FIG. 2, a conventional interdigital capacitor 22 includes a dielectric layer 24 formed on a substrate 10, and two capacitor electrodes 22a, 22b formed on the dielectric layer 24 with aligned in parallel to the substrate 20.

The conventional vertical type capacitor shown in FIG. 1 has advantages that if a thickness of the dielectric layer 14 interposed between the bottom electrode 12 and the top electrode 16 is reduced, a voltage required to change a capacitance can be sufficiently reduced, and a value of a capacitance can be calculated accurately, and since the size of the dielectric layer 14 is reduced, the dielectric layer can contribute less to the device loss otherwise causing larger loss in the entire device. However, the conventional vertical type capacitor shown in FIG. 1 has disadvantages that the bottom electrode 12 must be interposed between the substrate 10 and the dielectric layer 14 in the structure, and the interface control between the bottom electrode 12 and the dielectric layer 14 is necessary for electric stability of the device.

The conventional interdigital capacitor 22 shown in FIG. 2 has an advantage that its fabrication processes can be simplified since a bottom electrode is not necessary in the structure, but has a limitation to reducing a gap size between the capacitor electrodes 22a, 22b because of the limitation of a typical photolithography process. As a result, a size of the voltage applied to change a capacitance must be increased. Further, while calculation of an accurate value of a capacitance must be necessary in the designing of such a high frequency tunable device, since the capacitance value or permittivity value in the interdigital capacitor can be achieved through calculation of conformal mapping and approximation method unlike the capacitor structure illustrated in FIG. 1, the achieved value may be different from an actual value. Further, since a size of the interdigital capacitor of FIG. 2 is relatively larger than that of the vertical type capacitor of FIG. 1, an extent of contributing to the entire device loss by the interdigital capacitor of FIG. 2 is higher than that by the vertical type capacitor of FIG. 1.

### SUMMARY OF THE INVENTION

The present invention provides a tunable capacitor having-a new structure allowing its fabrication processes more simplified, ensuring its design with more easiness and diversity, and reducing its operation voltage than ever.

The present invention also provides a high frequency tunable device being newly structured to make its fabrication processes more simplified, ensure its design with more easiness and diversity, and provide a reduction effect of its device loss property.

According to an aspect of the present invention, there is provided a tunable capacitor including a dielectric layer formed on a substrate; and a first capacitor electrode and a second capacitor electrode formed on both sides of the dielectric layer on the substrate. The first capacitor electrode, the dielectric layer, and the second capacitor electrode are aligned in parallel on the substrate.

According to another aspect of the present invention, there is provided a high frequency tunable device including substrate; a signal line formed on the substrate; a plurality of tunable capacitors aligned on both sides of the signal line along the longitudinal direction of the signal line; and an electrode disposed on the substrate for applying a DC voltage to the tunable capacitors. The tunable capacitor includes a dielectric layer formed on the substrate, and a first capacitor electrode and a second capacitor electrode formed on both sides of the dielectric layer on the substrate, and the first capacitor electrode, the dielectric layer, and the second capacitor electrode are aligned in parallel on the substrate.

The dielectric layer of the tunable capacitor may be composed of a ferroelectric layer, a paraelectric layer or a combined layer thereof.

According to the present invention, there are provided a tunable capacitor and a high frequency tunable device having the tunable capacitor, in which an electrode, a ferroelectric, and an electrode of the tunable capacitor are aligned in parallel with each other on a substrate as a lateral structure of electrode-ferroelectric-electrode. Thus, a capacitor structure of electrode-ferroelectric/paraelectric-electrode can be provided without a process of forming a bottom electrode to form a capacitor. Therefore, its fabrication processes can be more simplified and fabrication costs can be reduced. Further, an electrical stability of the capacitor can be ensured through the simplification of a multi-layered thin film deposition process, and easiness and diversity of the design for the high frequency tunable device can be further ensured. Further, since the device operation voltage is reduced, an output efficiency of an entire system can be increased.

### BRIEF DESCRIPTION OF THE DRAWINGS

The above and other features and advantages of the present invention will become more apparent by describing in detail exemplary embodiments thereof with reference to the attached drawings in which:

FIG. 1 is a view illustrating a conventional vertical type capacitor;

FIG. 2 is a view illustrating a conventional interdigital type capacitor;

FIG. 3 is a view illustrating a tunable capacitor according to an embodiment of the present invention;

FIG. 4 is a view illustrating an exemplary structure of a high frequency tunable device according to an embodiment of the present invention;

FIGS. 5A through 5F are sectional views illustrating processing sequences of a method of fabricating a high frequency tunable device according to an embodiment of the present invention;

FIGS. 6A and 6B illustrate simulation results of a distributed analog phase shifter as an example of the high frequency tunable device according to the present invention, in which reflection loss and insertion loss are shown in the respective cases of using ferroelectric layers having different permittivities in accordance with frequency; and

FIGS. 7A and 7B illustrate simulation results of a distributed analog phase shifter as an example of the high frequency tunable device according to the present invention, in which phase shifts of transmission waves are shown in the respective cases of using ferroelectric layers having different permittivities in accordance with frequency.

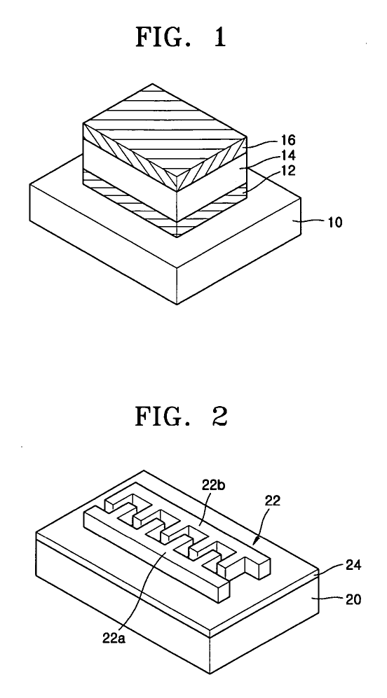

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. Like numbers refer to like elements throughout the specification.

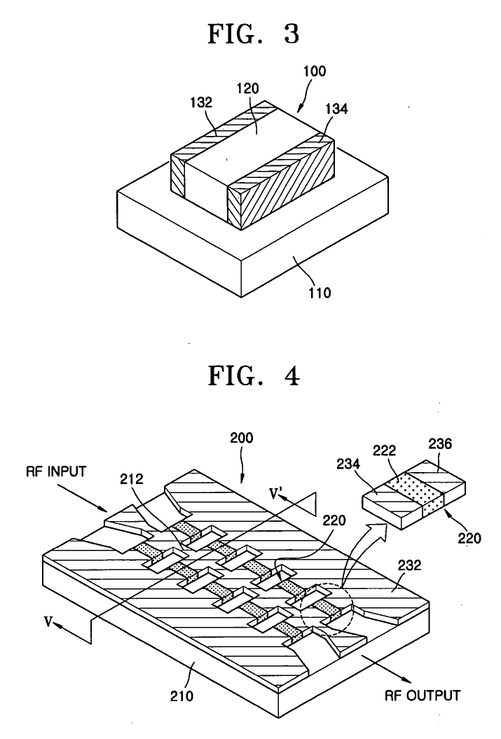

FIG. 3 is a view illustrating a tunable capacitor 100 according to an embodiment of the present invention.

The tunable capacitor 100 of the present invention includes a dielectric layer 120 formed on a substrate 110, and a first capacitor electrode 132 and a second capacitor electrode 134 formed on both sides of the dielectric layer 120 respectively on the substrate 110.

The first capacitor electrode 132, the dielectric layer 120, and the second capacitor electrode 134 are aligned in parallel on the substrate 110.

The substrate 110 may be formed of an oxide single crystal substrate, a ceramic substrate, or a semiconductor substrate such as silicon.

The dielectric layer 120 may be composed of a ferroelectric layer, a paraelectric layer, or a combined layer thereof. For example, the dielectric layer 120 may be formed of a barium strontium titanate (BST) layer.

The first capacitor electrode 132 and the second capacitor electrode 134 are composed of conductive metal. For example, the first capacitor electrode 132 and the second capacitor electrode 134 may be composed of Au/Cr.

As described above, the tunable capacitor of the present invention is a lateral type capacitor, which is composed of a substrate and a structure of electrode-dielectric layer-electrode aligned on the substrate in parallel with the substrate.

FIG. 4 is a view illustrating an exemplary structure of a high frequency tunable device according to an embodiment of the present invention. FIG. 4 illustrates a specific example of a distributed analog phase shifter as the high frequency tunable device according to the present invention.

Referring to FIG. 4, the high frequency tunable device 200 according to the present invention includes a signal line 212 formed on a substrate 210, and a plurality of tunable capacitors 220 formed on both sides of the signal line 212 with aligned along the longitudinal direction of the signal line 212. Further, an electrode 232 for applying a DC voltage to the tunable capacitor 220 is formed on the substrate 210. The substrate 210 may be formed of an oxide single crystal substrate, a ceramic substrate, or a semiconductor substrate such as silicon.

The tunable capacitor 220 includes a dielectric layer 222 formed on the substrate 210, and a first capacitor electrode 234 and a second capacitor electrode 236 formed on the substrate 210 on both sides of the dielectric layer 222. The first capacitor electrode 234, the dielectric layer 222, and the second capacitor electrode 236 are aligned in parallel on the substrate 210. The dielectric layer 222 of the tunable capacitor 220 may be composed of a ferroelectric layer, a paraelectric layer, or a combined layer thereof. For example, the dielectric layer 222 may be formed of a BST layer.

The electrode 232 may be formed integrally with the first capacitor electrode 234 or the second capacitor electrode 236, and each electrode may be composed of metal. Preferably, the electrode 232, the first capacitor electrode 234 and the second capacitor electrode 236 may be composed of Au/Cr.

The distributed analog phase shifter using the tunable capacitor illustrated in FIG. 4 is configured such that tunable capacitors, each including a substrate and a lateral type structure of electrode-dielectric layer-electrode aligned in parallel with the substrate are connected to a coplanar waveguide (CPW) having a high characteristic impedance. The CPW having lateral type tunable capacitors connected thereto may be regarded as a virtual transmission line having an increased line capacitance value as high as a capacitance value of the capacitor per cell, and a characteristic impedance of the virtual transmission line and a phase velocity thereof may vary with capacitance values of a tunable capacitor, which are changed in accordance with applied voltages.

As described above, the high frequency tunable device according to the present invention includes a tunable capacitor having a lateral structure of electrode-dielectric layer-electrode aligned in parallel with a substrate. Therefore, a device designing is easier and more diversified, and its fabrication processes can be simplified, and it has many advantages of a reduction of device operation voltage and the like.

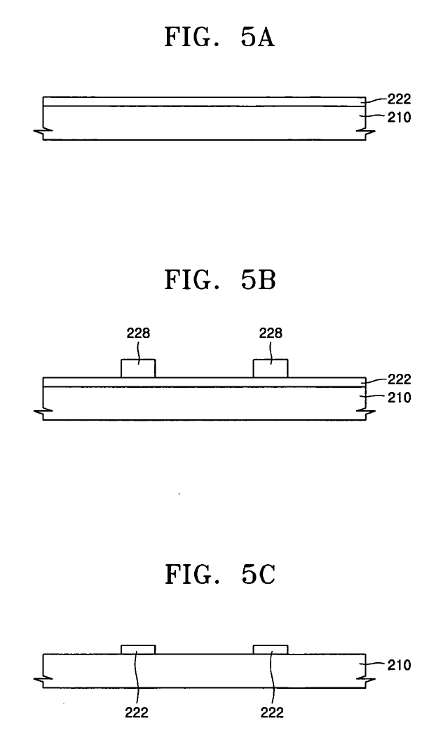

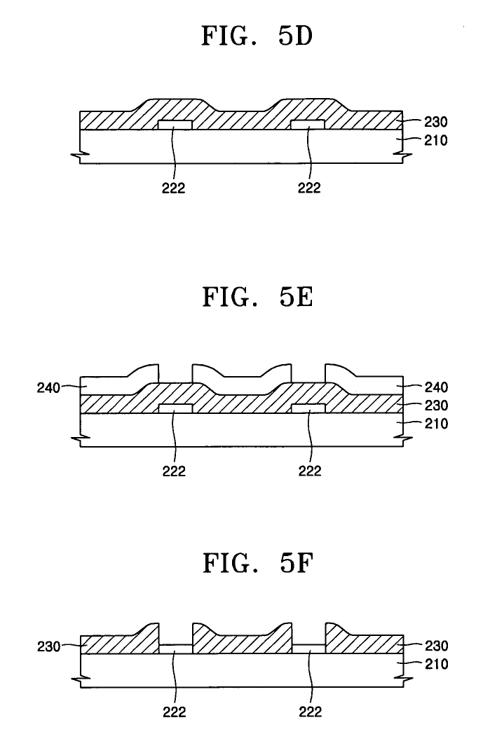

FIGS. 5A through 5F are sectional views illustrating processing sequences of a method of fabricating a high frequency tunable device according to an embodiment of the present invention. In specific, FIGS. 5A through 5F illustrates a method of fabricating the distributed analog phase shifter of FIG. 4. FIGS. 5A through 5F are sectional views taken along a line of V-V′ of FIG. 4. In FIGS. 5A through 5F, like numerals refer to like elements, and a detailed description thereof will be omitted.

Referring to FIG. 5A, a dielectric layer 222 is formed on the substrate 210.

Referring to FIG. 5B, a first mask pattern 228, for example, photoresist pattern is formed on the dielectric layer 222.

Referring to FIG. 5C, the dielectric layer 222 is etched using the first mask pattern 228 as an etch mask, and the remained first mask pattern 228 is removed using a typical method, for example, ashing and stripping process. As a result, the dielectric layer 222 is remained only in the tunable capacitor on the substrate 210, and the dielectric layer 222 is all removed in the rest portion.

Referring to FIG. 5D, a conductive layer 230 is formed on the substrate 210 where the dielectric layer 222 is remained only in the tunable capacitor portion. The conductive layer 230 may be formed of, for example, an Au/Cr layer.

Referring to FIG. 5E, a second mask pattern 240, for example, photoresist pattern is formed on the conductive layer 230. By the second mask pattern 240, an upper portion of the conductive layer 230 only on the dielectric layer 222 of the tunable capacitor is exposed.

Referring to FIG. 5F, the conductive layer 230 is etched, using the second mask pattern 240 as an etch mask, and the remained second mask pattern 240 is removed using a typical method, for example, ashing and stripping process. As a result, the conductive layer 230 is remained on the substrate 210 except for the portion on the dielectric layer 222 of the tunable capacitor. The conductive layer 230 constitutes the signal line 212, the electrode 232, the first capacitor electrode 234 and the second capacitor electrode 236 of FIG. 4.

In the method of fabricating the exemplary high frequency tunable device according to the present invention described in reference to FIGS. 5A through 5F, the dielectric layer is removed by etch except for the lateral type tunable capacitor portion. When the distributed analog phase shifter is fabricated by the method described as above, design can be precisely made in accordance with desired structures, and changes of a characteristic impedance and a phase velocity of CPW in accordance with applied voltages can be relieved.

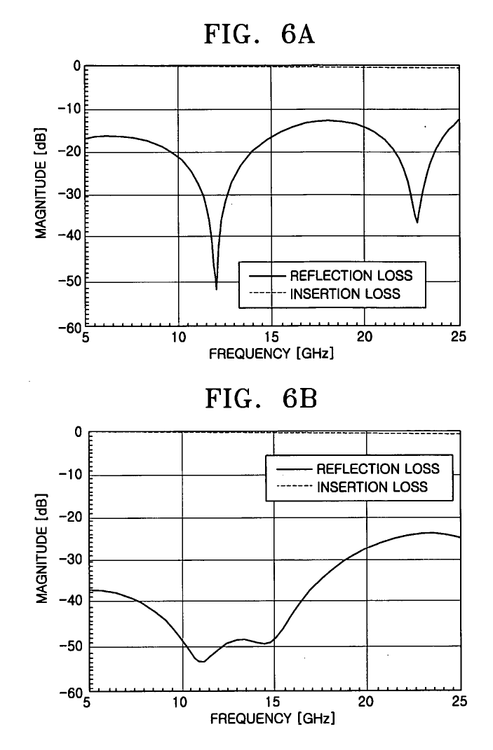

FIGS. 6A and 6B illustrate results of reflection loss and insertion loss in the distributed analog phase shifter having the lateral type tunable capacitor having electrode-ferroelectric-electrode in parallel with a substrate according to the present invention in accordance with frequency by a high frequency electromagnetic simulation (HFSS), in which permittivities of the dielectric layer are 1000 and 500 respectively.

For the evaluations of FIGS. 6A and 6B, the dielectric layer of the lateral type tunable capacitor formed on the MgO substrate used a BST thin film with a thickness of 400 nm. The electrode is composed of thick gold layer and thin chrome adhesion layer. A permittivity of the BST thin film of FIG. 6A is 1000, and a permittivity of the BST thin film of FIG. 6B is 500.

The results of reflection loss and insertion loss of FIGS. 6A and 6B are similar in shape and inclination to typical results achieved from capacitors employing the tunable capacitor having an interdigital structure or a vertical type electrode-ferroelectric-electrode structure vertically aligned on a substrate. That is, the return loss in the results of FIGS. 6A and 6B is about −15 dB or less in the frequency range of 5 to 25 GHz, and the insertion loss is about −0.5 dB or less, thereby showing a high possibility of being employed to a ferroelectric phase shifter.

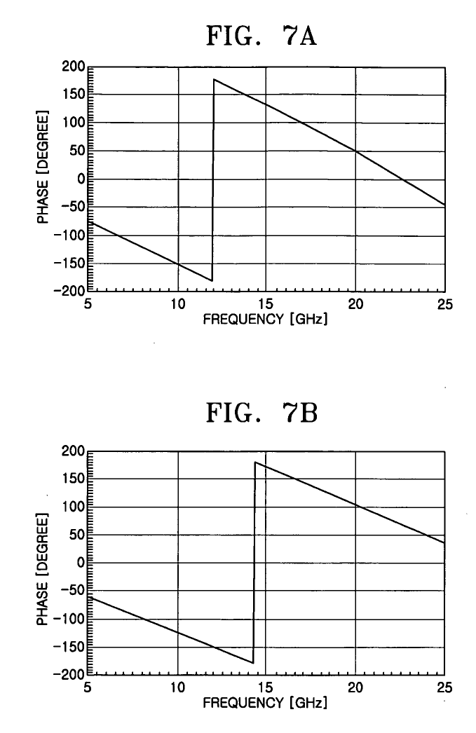

FIGS. 7A and 7B illustrate results of phase shifts of transmission waves in the distributed analog phase shifter having the lateral type tunable capacitor having electrode-ferroelectric-electrode in parallel with a substrate according to the present invention in accordance with frequency by a high frequency electromagnetic simulation (HFSS), in which permittivities of the BST thin films are 1000 and 500 respectively.

In FIGS. 7A and 7B, a difference of two phase shifts at 20 GHz was about 60 degrees, and a value of figure of merit (FOM), which is defined as differential phase shift/insertion loss (°/dB), was about 120°/dB at 20 GHz.

The embodiment has been described with an exemplary case of using a MgO substrate as a substrate of a high frequency tunable device, but the present invention is not limited thereto. The present invention can be employed to the cases of forming the high frequency tunable devices on different substrates. Further, the case of realizing the distributed analog phase shifter has been exemplified in this embodiment, but the present invention is not limited thereto. The present invention can be used in all kinds of high frequency tunable devices such as a voltage tunable capacitor, a voltage tunable resonator, a voltage tunable filter, a phase shifter, a distributor, a voltage controlled oscillator, and the like.

The tunable capacitor according to the present invention has a lateral type structure of electrode-ferroelectric-electrode in parallel with a substrate. The high frequency tunable device according to the present invention having the lateral type capacitor has a structure of electrode-ferroelectric/paraelectric-electrode without a deposition process of forming a bottom electrode to form a capacitor, thereby simplifying the fabrication processes and reducing fabrication costs. Accordingly, an electrical stability of the capacitor can be ensured through the simplification of a multi-layered thin film deposition process, and easiness and diversity of the design for the high frequency tunable device using the same can be also ensured. Further, the present invention provides an advantage of increasing an output efficiency of an entire system by the reduction of a device operation voltage.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A tunable capacitor comprising:
a dielectric layer formed on a substrate; and
a first capacitor electrode and a second capacitor electrode formed on both sides of the dielectric layer on the substrate, wherein
the first capacitor electrode, the dielectric layer, and the second capacitor electrode are aligned in parallel on the substrate.

2. The tunable capacitor according to claim 1, wherein the dielectric layer is composed of a ferroelectric layer, a paraelectric layer or a combined layer thereof.

3. A high frequency tunable device comprising:
a substrate;
a signal line formed on the substrate;
a plurality of tunable capacitors aligned on both sides of the signal line along the longitudinal direction of the signal line; and
an electrode disposed on the substrate for applying a DC voltage to the tunable capacitors, wherein
the tunable capacitor comprises a dielectric layer formed on the substrate, and a first capacitor electrode and a second capacitor electrode formed on both sides of the dielectric layer on the substrate, and
the first capacitor electrode, the dielectric layer, and the second capacitor electrode are aligned in parallel on the substrate.

4. The high frequency tunable device according to claim 3, wherein the substrate is formed of an oxide single crystal substrate, a ceramic substrate, or a semiconductor substrate.

5. The high frequency tunable device according to claim 3, wherein the dielectric layer of the tunable capacitor is composed of a ferroelectric layer, a paraelectric layer or a combined layer thereof.

6. The high frequency tunable device according to claim 3, wherein the dielectric layer of the tunable capacitor includes barium-strontium-titanate (BST).

7. The high frequency tunable device according to claim 3, wherein the first capacitor electrode and the second capacitor electrode are composed of Au/Cr respectively.
